(19) United States
(12) Patent Application Publication
(10) Pub. No.: US 2026/0096311 A1
(43) Pub. Date: Apr. 2, 2026

(54) DISPLAY PANEL

(71) Applicant: HKC CORPORATION LIMITED, SHENZHEN (CN)

(72) Inventors: Yao LI, SHENZHEN (CN); Pei XU, SHENZHEN (CN)

(73) Assignee: HKC CORPORATION LIMITED, SHENZHEN (CN)

(21) Appl. No.: 19/321,237

(22) Filed: Sep. 7, 2025

(30) Foreign Application Priority Data
Sep. 30, 2024 (CN) 202411396585.3

(51) Int. Cl. H10K 59/127; H10K 59/80

(52) U.S. Cl. CPC H10K 59/1275; H10K 59/8794

(57) ABSTRACT

A display panel includes: a glass substrate, a plurality of light emitting units, a plurality of first bonding portions, a silicon-based driver substrate. The glass substrate includes a first surface and a second surface opposite to the first. The silicon-based driver substrate includes a protection layer. A side of the second surface side and a side of the protection layer facing the glass substrate cooperatively form a plurality of receiving spaces. Each receiving space receives an excitation member and a drive member. The excitation member provides excitation to drive the drive member to apply a pressure to the glass substrate and the protection layer.

### CROSS REFERENCE TO RELATED APPLICATIONS

The present application claims the priority of the Chinese patent application No. 202411396585.3, filed on Sep. 30, 2024, contents of which are incorporated herein by its entireties.

### TECHNICAL FIELD

Embodiments of the present disclosure relate to the technical field of displaying, and more specifically, to a display panel.

### BACKGROUND

A monocrystalline silicon driver backplane is a driver substrate which takes a semiconductor device formed based on a complementary metal oxide semiconductor (CMOS) process as a driver unit. Compared to an active-matrix organic light-emitting diode (AMOLED) panel which takes an amorphous silicon, a microcrystalline silicon, or a low-temperature polycrystalline silicon thin-film transistor as the backplane, the monocrystalline silicon driver backplane may have a higher carrier mobility. Therefore, a silicon-based organic light-emitting diode (OLED) display panel may be a best performance display panel to be used in AR/VR products.

Currently, for the silicon-based OLED display panel, an externally-bound display chip may be integrated into the silicon-based driver backplane. A preparation method thereof is to perform evaporation to form the OLED device on the silicon-based driver substrate. Specific processes include: firstly performing deposition to form an anode, then preparing a pixel defining layer, and then performing deposition to successively form an organic light emitting layer and a cathode. In this way, smaller-sized pixel units may be prepared, and displaying finesse even better than retina may be achieved, such that a high resolution, high integration, lower power consumption, a small size, and a light weight, can be achieved.

However, direct evaporation to form the OLED device on silicon-based driver substrate may affect a silicon-based driver circuit, resulting in damage to the driver circuit, such that the driver circuit may be unusable, increasing manufacturing costs.

### SUMMARY

The present disclosure provides a display panel and a method of manufacturing the display panel, so as to solve the technical problem of circuit damages caused by direct evaporation to form the OLED device on silicon-based driver substrate.

In a first aspect, the present disclosure provides a display panel, including:
a glass substrate, including a first surface and a second surface opposite to the first surface, where the glass substrate defines a plurality of conductive through holes extending from the first surface to the second surface; the plurality of the conductive through holes include a plurality of first conductive through holes;
a plurality of light emitting units, arranged on the first surface of the glass substrate; each of the plurality of light emitting units includes an anode electrode, an organic light emitting layer, and a cathode electrode that are stacked sequentially in a direction away from the glass substrate;
a plurality of first bonding portions, where each of the plurality of first bonding portions is received in a respective one of the plurality of first conductive through holes; each of the plurality of first bonding portions is electrically connected, through the respective first conductive through hole, to the anode electrode of a respective one of the plurality of light emitting units;
a silicon-based driver substrate, arranged at a side of the second surface of the glass substrate and including a protection layer and a plurality of first bonding electrodes arranged on a side of the silicon-based driver substrate near the glass substrate; where the plurality of first bonding electrodes are aligned to and bonded with the plurality of first bonding portions in one-to-one correspondence manner; at least part of the plurality of first bonding electrodes are embedded in the protection layer.

A side of the second surface side of the glass substrate and a side of the protection layer facing the glass substrate cooperatively form a plurality of receiving spaces; each of the plurality of receiving spaces receives an excitation member and a drive member; the excitation member is configured to provide excitation; in response to the excitation provided by the excitation member, the drive member is configured to apply a pressure to the glass substrate and the protection layer, respectively.

### BRIEF DESCRIPTION OF THE DRAWINGS

FIG. 1 is a structural schematic view of a display panel according to an embodiment of the present disclosure.

FIG. 2 is an enlarged view of a portion A in the display panel shown in FIG. 1.

FIG. 3 is a structural schematic view of a receiving space shown in FIG. 2.

FIG. 4 is a structural schematic view of a glass substrate of the display panel shown in FIG. 1.

FIG. 5 is a structural schematic view of the glass substrate according to another embodiment of the present disclosure.

FIG. 6 is a structural schematic view of the glass substrate according to still another embodiment of the present disclosure.

FIG. 7 is a structural schematic view of the receiving space according to a second embodiment of the present disclosure.

### REFERENCE NUMERALS IN THE DRAWINGS

1—glass substrate; 2—light emitting unit; 3—pixel defining layer; 4—first bonding portion; 5—receiving space; 6—silicon-based driver substrate; 7—second bonding portion; 8—encapsulation layer; 11—first surface; 12—second surface; 13—conductive through holes; 21—anode electrode; 22—organic light emitting layer; 23—cathode electrode; 51—excitation member; 52—drive member; 53—drying layer; 61—first bonding electrode; 62—protection layer; 63—silicon substrate; 64—driver circuit; 65—second bonding electrode; 501—first recess; 502—second recess; 511—heat generation layer; 521—reaction layer.

### DETAILED DESCRIPTIONS

The technical solutions in the embodiments of the present disclosure will be clearly and completely described below by referring to the accompanying drawings in the embodiments of the present disclosure. Apparently, the described embodiments are only a part of, not all of, the embodiments of the present disclosure. All other embodiments, which are obtained by any ordinary skilled person in the art based on the embodiments in the present disclosure without making creative work, shall fall within the scope of the present disclosure.

Terms “first”, “second”, and “third” in the present disclosure are used for descriptive purposes only and are not to indicate or imply relative importance or implicitly specifying the number of technical features. Therefore, a feature defined with “first”, “second”, “third” may include at least one such feature, either explicitly or implicitly. In the description of the present disclosure, “a plurality of” means at least two, such as two, three, and so on, unless otherwise expressly and specifically limited. All directional indications (such as up, down, left, right, front, rear . . . ) in the embodiments of the present disclosure are only used to explain a relative positional relationship and movement between components at a particular attitude (the attitude as shown in the accompanying drawings). The directional indication may be changed accordingly when the particular attitude is changed. Furthermore, terms “include” and “have” and any variations thereof are intended to cover non-exclusive inclusion. For example, a process, a method, a system, a product or an apparatus including a series of steps or units is not limited to the listed steps or units, but may further include steps or units that are not listed or steps or units that are inherently included in the process, the method, the system, the product or the apparatus.

Reference to “embodiments” herein means that particular features, structures, or characteristics described in an embodiment may be included in at least one embodiment of the present disclosure. The phrase at various sections in the specification does not necessarily refer to one same embodiment, nor separate or alternative embodiments that are mutually exclusive of other embodiments. Any ordinary skilled person in the art shall understand that, both explicitly and implicitly, the embodiments described herein may be combined with other embodiments.

The present disclosure will be described in detail by referring to drawings and embodiments.

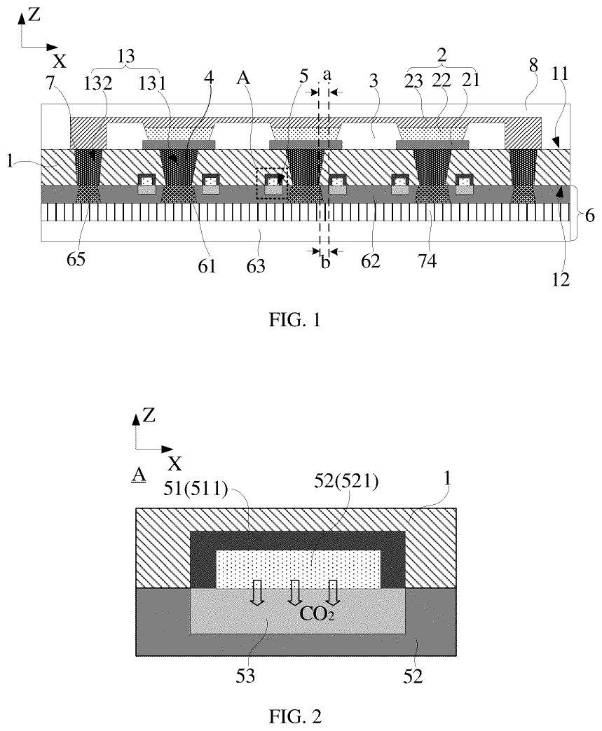

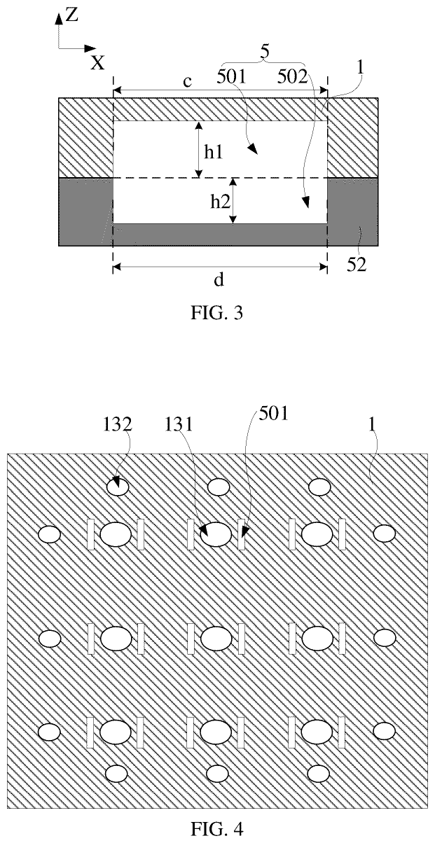

As shown in FIG. 1, FIG. 1 is a structural schematic view of a display panel according to an embodiment of the present disclosure; as shown in FIG. 2, FIG. 2 is an enlarged view of a portion A in the display panel shown in FIG. 1. The present disclosure provides a display panel, which may be an OLED display panel. The display panel may include a glass substrate 1, a plurality of light emitting units 2, a plurality of first bonding portions 4, and a silicon-based driver substrate 6.

The glass substrate 1 may include a first surface 11 and a second surface 12 opposite to the first surface 11. The glass substrate 1 defines a plurality of conductive through holes 13 extending from the first surface 11 to the second surface 12. The plurality of conductive through holes 13 may include a plurality of first conductive through holes 131. Compared to through holes in silicon material, through holes in glass may provide excellent high-frequency electrical characteristics, have low costs, may be achieved by performing simple processes, and may be highly mechanically stable.

The plurality of light emitting units 2 may be disposed on the first surface 11 of the glass substrate 1. Each of the plurality of light emitting units 2 may include an anode electrode 21, an organic light emitting layer 22, and a cathode electrode 23 that are stacked sequentially in a direction extending away from the glass substrate 1. Specifically, the first surface 11 of the glass substrate 1 is further arranged with a pixel defining layer 3. The pixel defining layer 3 protrudes out of the glass substrate 1, and the pixel defining layer 3 and the glass substrate I enclose to form a plurality of pixel receiving regions (not shown in the figure). The plurality of light emitting units 2 are arranged within the plurality of pixel receiving regions. The plurality of pixel receiving regions are arranged in one-to-one correspondence with the plurality of first conductive through holes 131.

The anode electrode 21 may be arranged on a surface of the glass substrate 1 exposed through the pixel receiving regions. The pixel defining layer 3 may cover an edge of the anode electrode 21 so as to prevent the anode electrode 21 of one of the plurality of light emitting units 2 from contacting the anode electrode 21 of an adjacent one of the plurality of light emitting units 2, such that signal crosstalk may be prevented. The organic light emitting layer 22 may be disposed on a side of the anode electrode 21 away from the glass substrate 1. The cathode electrode 23 may be disposed on a side of the organic light emitting layer 22 away from the anode electrode 21 and cover the organic light emitting layer 22. Specifically, one integral cathode electrode 23 may be arranged and extending to cover the organic light emitting layer 22 of each of the plurality of light emitting units 2. The one integral cathode electrode 23 forms one integral common cathode. The one integral common cathode has a plurality of portions disposed corresponding to the plurality of light emitting units 2, such that each of the plurality of portions serves as the cathode electrode 23 for a respective one of the plurality of light emitting units 2. The anode electrode 21 and the cathode electrode 23 may transmit an anode drive signal and a cathode drive signal, respectively, to the organic light emitting layer 22 to drive the organic light emitting layer 22 to emit light.

In some embodiments, the plurality of light emitting units 2 may include light emitting units 2 that emit light in different colors, such as a red light emitting unit 2, a green light emitting unit 2, and a blue light emitting unit 2, such that colorful displaying may be achieved. Specifically, a light color of each light emitting unit 2 may be determined by a light color of the organic light emitting layer 22. Alternatively, in some embodiments, the plurality of light emitting units 2 may emit light in one same color, such as white, red, green, blue, or any other color, which may be determined according to the actual needs. For example, the light emitting unit 2 may emit light in white, and brightness of the light emitting unit 2 may be adjusted to achieve grayscale displaying. A color resistant layer may be arranged on top of the light emitting unit 2 to achieve the colorful displaying. For example, the plurality of light emitting units 2 may emit light in blue, and a red quantum dot layer may be arranged above a portion of the plurality of light emitting units 2, and a green quantum dot layer may be arranged above another portion of the light emitting units 2, such that the colorful displaying may be achieved.

The plurality of first bonding portions 4 may be arranged on the second surface 12 of the glass substrate 1. Each of the plurality of first bonding portions 4 may be at least partially received in a respective one of the plurality of first conductive through holes 131. Each of the plurality of bonding portions 4 may be electrically connected to the anode electrode 21 through the respective one of the plurality of first conductive through hole 13 to transmit the anode drive signal to the anode electrode 21 of a respective one of the plurality of light emitting units 2 through the respective first conductive through hole 13.

The silicon-based driver substrate 6 is arranged on a side of the second surface 12 of the glass substrate 1. The silicon-based driver substrate 6 may further include a plurality of first bonding electrodes 61. The plurality of first bonding electrodes 61 are one-to-one correspondingly aligned to and bonded to the plurality of first bonding portions 4 to control the plurality of light emitting units 2 corresponding to the plurality of first bonding portions 4 to emit light. Specifically, the silicon-based driver substrate 6 may further include a silicon substrate 63 and a driver circuit 64 stacked on the silicon substrate 63. The silicon substrate 63 may refer to a substrate plate having a monocrystalline silicon material as a basis. The driver circuit 54 may be electrically connected to the plurality of first bonding electrodes 61 to transmit the anode drive signal to the anode electrode 21 through the respective first bonding portion 4. Specifically, the driver circuit 64 may include an active driver circuit integrated on a monocrystalline silicon substrate based on a CMOS (Complementary Metal-Oxide-Semiconductor) process. Specifically, the driver circuit 64 may include a plurality of “3T1C” structures (three thin-film transistors and one capacitor) to independently control each of the plurality of light emitting units 2 to achieve high-quality displaying.

The silicon-based driver substrate 6 may further include a protection layer 62 arranged on a side near the glass substrate 1. At least part of each first bonding electrode 61 may be embedded in the protection layer 62. The protection layer 62 may be configured to protect the driver circuit 64 from corrosion caused by external water steams. A material of the protection layer 62 may be an inorganic insulating material, such as silicon dioxide, silicon nitride, or silicon nitride oxide.

The silicon-based driver substrate 6 may further include a display control circuit (not shown) electrically connected to the driver circuit 64. The display control circuit may control, through the driver circuit 64, the plurality of light emitting units 2 to display contents. The display control circuit may be an integrated circuit (IC) integrated on the silicon-based driver substrate 6.

By arranging the plurality of light emitting units 2 and the plurality of first bonding portions 4 respectively on two opposite surfaces of the glass substrate 1, each of the plurality of first bonding portions 4 may be electrically connected, through the respective one of the plurality of first conductive through holes 131, to the anode electrode 21 of the respective one of the plurality of light emitting units 2. In this way, the plurality of light emitting units 2 may be electrically coupled with the silicon-based driver substrate 6, such that the silicon-based driver substrate 6 may drive the plurality of light emitting units 2 to emit light. Therefore, the plurality of light emitting units 2 may be not be directly prepared on the silicon-based driver substrate 6, damages to the pixel driver circuit 64, which may be caused by directly preparing the plurality of light emitting units 2 on the silicon-based driver substrate 6, may be avoided, and the product yield may not be reduced.

The second surface 12 of the glass substrate 1 a side surface of the protection layer 62 facing the glass substrate 1 cooperatively form a receiving space 5. Specifically, the receiving space 5 may be defined only in the second surface 12 of the glass substrate 1, or only on the side surface of the protection layer 62 facing the glass substrate 1, or in the glass substrate 1 and the protection layer 62 respectively.

As shown in FIG. 2, an excitation member 51 and a drive member 52 may be received in the receiving space 5. The excitation member 51 may be configured to provide excitation. In response to the excitation provided by the excitation member 51, the drive member 52 may apply a pressure to the glass substrate 1 and the protection layer 62, enabling the glass substrate 1 and the protection layer 62 to at least have a tendency to separate apart from each other. Specifically, the excitation provided by the excitation member 51 may be any common excitation, such as thermal excitation or electrical excitation, as long as the drive member 52 can be excited in a particular situation. The drive member 52 may apply the pressure to the glass substrate 1 and the protection layer 62 by volumetric expansion, such as thermal expansion or gas expansion, which may be achieved by having a chemical reaction to generate gas so as to apply the pressure to the glass substrate 1 and the protection layer 62.

By arranging the excitation member 51 and the drive member 52 in the receiving space 5 between the glass substrate 1 and the silicon-based driver substrate 6, when the glass substrate 1 and the silicon-based driver substrate 6 need to be peeled off and separated from each other due to a process problem occurring during preparing the display panel, the drive member 52 can be excited by the excitation member 51 to apply the pressure in opposite directions to the glass substrate 1 and the silicon-based driver substrate 6, respectively, enabling the glass substrate 1 and the silicon-based driver substrate 6 to be peeled apart from each other more easily. In this way, a peeling efficiency may be effectively improved.

In an embodiment, the excitation member 51 may include a heat generation layer 511. The drive member 52 may include a reaction layer 521. The heat generation layer 511 may be configured to generate heat and heat the reaction layer 521, such that a temperature of the reaction layer 521 may reach a predetermined temperature, i.e., a minimum temperature at which a chemical reaction can occur in the reaction layer 521. In response to the temperature of the reaction layer 521 being greater than the predetermined temperature, the chemical reaction occurs in the reaction layer 521 to generate a gas, such that an air pressure in the receiving space 5 may be increased, and the high-pressure gas gathered in the receiving space 5 may apply the pressure on the glass substrate 1 and the protection layer 62, respectively. In this way, the glass substrate 1 and the protection layer 62 may be peeled apart from each other more easily.

In the present embodiment, the heat generation layer 511 may include a wave-absorbing material, configured to convert ultrasonic waves absorbed by the heat generation layer 511 into thermal energy to heat the reaction layer 521. Specifically, the heat generation layer 511 may be a wave-absorbing material that may absorb, after being irradiated by ultrasonic waves, acoustic energy and convert the acoustic energy into the thermal energy. For example, the wave-absorbing material may be carbon nanotubes, graphene, metal nanoparticles, polymeric materials, and magnetic nanoparticles, and so on. The heat generation layer 511 may alternatively be a wave-absorbing material that may absorb, after being irradiated by electromagnetic waves, electromagnetic energy and convert the electromagnetic energy into the thermal energy. For example, the wave-absorbing material may be carbon nanotubes, graphene, conductive polymers, metal nanoparticles, porous ceramic materials, and magnetic nanoparticles, and so on.

Specifically, the heat generation layer 511 may be a carbon nanotube composite layer. The carbon nanotube composite layer may generate heat under excitation of ultrasonic waves at a preset frequency to heat the reaction layer 521. The preset frequency may be an ultrasound frequency that is different from an ultrasound frequency used for fingerprint identification or other functions and that is different from an ultrasound frequency commonly occurring in ambient environments. In this way, the heat generation layer 511 of the display panel may be prevented from being mistakenly triggered to be excited in daily use.

In an embodiment, the preset frequency may be 8 GHz to 40 GHz. A polyester-based composite material in the carbon nanotube composite layer may have ideal wave-absorbing performance in a frequency range of 8 GHz to 40 GHz. A reduced graphene oxide aerogel wave-absorbing material in the carbon nanotube composite layer may have ideal wave-absorbing performance in a frequency range of 18 GHz to 26.5 GHz. A multi-wall carbon nanotube/glass fiber/epoxy resin composite may have ideal wave-absorbing performance in a frequency range of 26.5 GHz to 40 GHz.

Of course, in other embodiments, the heat generation layer 511 may alternatively be a resistance wire. In these embodiments, the heat generation layer 511 may be electrically connected to the driver circuit 64 in the silicon-based driver substrate 6 to convert electrical energy into the thermal energy. Specifically, in response to the driver circuit 64 transmitting electrical signals to the heat generation layer 511, the heat generation layer 511 may generate heat and heat the reaction layer 521, enabling the reaction layer 521 to generate the gas. It can be understood that, compared to passive heat generation in which the heat generation layer 511 may be irradiated to be mistakenly triggered to provide excitation, a completely active heat generation controlled based on the electrical signals can eliminate any mistaken triggering for the excitation. For the completely active heat generation, the heat generation layer 511 may be precisely controlled by the electrical signals, such that it is ensured that the heat generation layer 511 may be heated only when needed, and systemic reliability and controllability may be improved.

The reaction layer 521 may be a magnesium bicarbonate nanoparticle film. The magnesium bicarbonate nanoparticle film, in response to a temperature of the magnesium bicarbonate nanoparticle film being greater than the predetermined temperature, the magnesium bicarbonate may undergo a decomposition reaction to generate water vapor and carbon dioxide. A large amount of carbon dioxide in a gas phase may cause the air pressure in the receiving space 5 to increase, such that the high-pressure gas gathered in the receiving space 5 may apply the pressure on the glass substrate 1 and the protection layer 62, respectively. The predetermined temperature may be greater than or equal to 180° C. and less than or equal to 220° C. Specifically, the predetermined temperature may be any value of 180° C., 190° C., 200° C., 210° C., or 220° C. It is understood that the magnesium bicarbonate nanoparticle material is used as the reaction layer 521 because the gas generated from the decomposition reaction is carbon dioxide, which may not cause corrosion on the display panel.

As shown in FIG. 2, furthermore, a drying layer 53 may be received in the receiving space 5 to absorb the water vapor generated from the decomposition reaction of the reaction layer 521. In this way, other structural film layers of the display panel may be prevented from being corroded by the water vapor generated by the reaction layer 521. Specifically, the drying layer 53, the reaction layer 521, and the heat generation layer 511 may be sequentially stacked along a stacking direction Z of the display panel in the receiving space 5. In this way, the heat generation layer 511 and the reaction layer 521 are tightly attached to each other, and heat of the heat generation layer 511 may be quickly and efficiently transferred to the reaction layer 521. Furthermore, the reaction layer 521 and the drying layer 53 are tightly attached to each other, and the drying layer 53 may absorb the water vapor generated by the reaction layer 521 as much as possible, and therefore, the water vapor leakage may be avoided as much as possible.

In some embodiments, as shown in FIG. 2, the heat generation layer 511 may further wrap a side surface of the reaction layer 521 away from the drying layer 53 and two side surfaces of the reaction layer 521 located along a first direction X that is perpendicular to the stacking direction Z. In this way, a contact area between the heat generation layer 511 and the reaction layer 521 may be increased, a heating efficiency may be improved.

Of course, in other embodiments, the drying layer 53, the reaction layer 521, and the heat generation layer 511 may alternatively be sequentially arranged along the first direction X in the receiving space 5.

As shown in FIG. 3, FIG. 3 is a structural schematic view of the receiving space shown in FIG. 2. In an embodiment, one of the second surface 12 of the glass substrate 1 and the side surface of the protection layer 62 facing the glass substrate 1 may define a plurality of first recesses 501, and the other one of the second surface 12 of the glass substrate 1 and the side surface of the protection layer 62 facing the glass substrate 1 may define a plurality of second recesses 502. Each of the plurality of first recesses 501 and a respective one of the plurality of second recesses 502 may be communicated to each other to form one receiving space 5 to receive the heat generation layer 511, the reaction layer, and the drying layer 53. The heat generation layer 511 and the reaction layer 521 may be received in the first recess 501, and the drying layer 53 may be received in the second recess 502. The drying layer 53 may be disposed on the side surface of the reaction layer 521 away from the heat generation layer 511. In this way, the gas generated by the reaction layer 521 may be gathered in the receiving space 5 formed by the first recess 501 and the second recess 502, and the air pressure in the receiving space 5 may be increased, such that the high-pressure gas gathered in the receiving space 5 may apply the pressure on the glass substrate 1 and the protection layer 62, respectively, enabling the glass substrate 1 and the protection layer 62 to be more easily peeled apart from each other.

Specifically, a projection of each of the plurality of second recesses 502 on the glass substrate 1 along the stacking direction of the display panel at least partially coincides with a projection of the respective one of the plurality of first recesses 501 on the glass substrate 1 along the stacking direction Z. In this way, the respective first recess 501 and the respective second recess 502 may be communicated to each other, such that the water vapor generated by the reaction layer 521 received in the first recess 501 may be absorbed by the drying layer 53 received in the second recess 502. In some embodiments, as shown in FIG. 3, the projection of each second recess 502 on the glass substrate 1 along the stacking direction Z of the display panel coincides exactly with the projection of the respective first recess 501 on the glass substrate 1 along the stacking direction Z. A shape of each of the first recess 501 and the second recess 502 may be in any one of: rectangular, circular, or triangular. The shape of the first recess 501 may be the same as or different from the shape of the second recess 502.

Of course, in other embodiments, the projection of the first recess 501 may be located inside the projection of the respective second recess 502; alternatively, the projection of the second recess 502 may be located inside the projection of the respective first recess 501, as long as the first recess 501 and the second recess 502 can be communicated to each other.

Specifically, as shown in FIG. 3, the plurality of first recesses 501 may be defined in the second surface 12 of the glass substrate 1; and each first recess 501 may extend from the second surface 12 of the glass substrate 1 along the stacking direction Z towards the light emitting unit 2. A depth h1 of the first recess 501 may be less than or equal to one-third of a thickness of the glass substrate 1, such that the first recess 501 may not reduce structural strength of the glass substrate 1.

The second recess 502 may be defined in the side surface of the protection layer 62 facing the glass substrate 1. The second recess 502 may extend from the side surface of the protection layer 62 near the glass substrate 1 along the stacking direction Z toward the silicon-based driver substrate 6. A depth h2 of the second recess 502 may be less than or equal to one-half of a thickness of the protection layer 62, such that anti-corrosion performance of the protection layer 62 may not be affected.

As shown in FIG. 1, the first recess 501 may be spaced apart from the first conductive through hole 13, such that transmission of anode drive signals in the display panel through the first conductive through hole 13 may not be affected. A distance a between the first recess 501 and the first conductive through hole 13 may be greater than or equal to 2 μm and less than or equal to 3 μm, ensuring that, while the first recess 501 and the first conductive through hole 13 are spaced apart from each other, the plurality of first recesses 501 may be densely arranged on the glass substrate 1. Specifically, the distance a between the first recess 501 and the first conductive through hole 13 may be in any value of: 2 μm, 2.2 μm, 2.5 μm, 2.8 μm, and 3 μm.

The second recess 502 may be spaced apart from the first bonding electrode 61, such that the first bonding electrode 61 may be prevented from being corroded by the water vapor. A distance b between the second recess 502 and the first bonding electrode 61 may be greater than or equal to 2 μm and less than or equal to 3 μm, ensuring that the plurality of second recesses 502 may be densely arranged on the protection layer 62. Specifically, the distance b between the second recess 502 and the first bonding electrode 61 may be in any value of: 2 μm, 2.2 μm, 2.5 μm, 2.8 μm, and 3 μm.

A width c of the first recess 501 may be greater than or equal to 1 μm and less than or equal to 1.5 μm, ensuring that the first recess 501 may have sufficient space to receive the heat generation layer 511 and the reaction layer 521 without affecting a dense arrangement of the first bonding electrodes 61. Specifically, the width c of the first recess 501 may be in any value of 1 μm, 1.1 μm, 1.2 μm, 1.3 μm, and 1.5 μm. Similarly, a width d of the second recess 502 may be greater than or equal to 1 μm and less than or equal to 1.5 μm, ensuring that the second recess 502 has sufficient space to receive the drying layer 53 without affecting a dense arrangement of the first conductive through holes 131. Specifically, the width c of the first recess 501 may be in any value of 1 μm, 1.1 μm, 1.2 μm, 1.3 μm, and 1.5 μm.

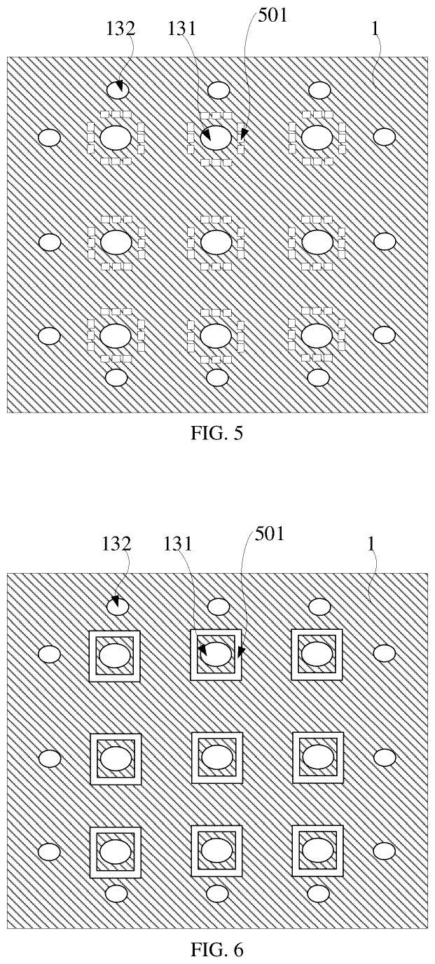

As shown in FIG. 1 and FIG. 4, FIG. 4 is a structural schematic view of the glass substrate of the display panel shown in FIG. 1. In an embodiment, for each first conductive through hole 13, two first recesses 501 may be arranged respectively at two sides of the first conductive through hole 13 along the first direction X, such that the glass substrate 1 and the silicon-based driver substrate 6 may be peeled apart from each other more easily. Specifically, the two first recesses 501 may be distributed symmetrically about the first conductive through hole 13.

As shown in FIG. 5, FIG. 5 is a structural schematic view of the glass substrate according to another embodiment of the present disclosure. In an embodiment, one first recess 501 may further include a plurality of sub recesses. The plurality of sub-recesses may be spaced apart from each other and surround a circumference of the first conductive through hole 13 to further enable the glass substrate 1 and the silicon-based driver substrate 6 to be peeled apart from each other more easily.

As shown in FIG. 6, FIG. 6 is a structural schematic view of the glass substrate according to still another embodiment of the present disclosure. In an embodiment, a shape of the projection of the first recess 501 on the glass substrate 1 along the stacking direction may be annular, i.e., the first recess 501 is disposed surrounding the first conductive through hole 13 to further enable the glass substrate 1 and the silicon-based driver substrate 6 to be peeled apart from each other more easily. Specifically, the first recess 501 and the first conductive through hole 13 may be coaxially arranged to each other.

As shown in FIG. 1, in an embodiment, the plurality of conductive through holes 13 may further include a plurality of second conductive through holes 132 that are located at a circumferential periphery of the plurality of first conductive through holes 131. The display panel may further include a plurality of second bonding portions 7. Each of the plurality of second bonding portions 7 may be at least partially received in a respective one of the plurality of second conductive through holes 132. Each of the plurality of second bonding portions 7 may be electrically connected to the cathode electrode 23 via the respective second conductive through hole 13 to transmit the cathode drive signal to the cathode electrode 23 of the respective light emitting unit 2 via the respective second conductive through hole 13. The silicon-based driver substrate 6 may further include a plurality of second bonding electrodes 65. Each of the plurality of second bonding electrodes 65 may be aligned and bonded with a respective one of the plurality of second bonding portions 7. The silicon-based driver substrate 6 may transmit the cathode drive signal to the cathode electrode 23 through the second bonding electrode 65 and the second bonding portion 7 to control the light emitting unit 2 to emit light.

As shown in FIG. 1, in an embodiment, the glass substrate 1 is further arranged with an encapsulation layer 8 to protect the plurality of light emitting units 2 on the glass substrate 1, isolating the external water and oxygen and avoiding failure of the light emitting units 2 caused by invasion of the water and the oxygen. Specifically, the encapsulation layer 8 may cover a side surface of the cathode electrode 23 away from the anode electrode 21 and may lap over a portion of a surface of the glass substrate 1 that is not covered by the light emitting units 2.

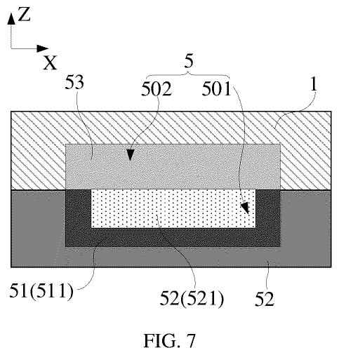

As shown in FIG. 7, FIG. 7 is a structural schematic view of the receiving space according to a second embodiment of the present disclosure. A structure of the display panel provided in the second embodiment is substantially the same as a structure of the display panel provided in the first embodiment. In the second embodiment, the first recess 501 may be defined in the side surface of the protection layer 62 facing the glass substrate 1, and the second recess 502 may be defined in the second surface 12 of the glass substrate 1. It can be understood that after the glass substrate 1 and the silicon-based driver substrate 6 are peeled apart from each other, the silicon-based driver substrate 6 may be retained, and the heat generation layer 511, the reaction layer 521, and the drying layer 53 may be replaced with new ones, and the silicon-based driver substrate 6 may be cyclically used. By defining the first recess 501 having the heat generation layer 511 in the protection layer 62 of the silicon-based driver substrate 6, as the silicon-based driver substrate 6 may be retained in the protection layer 62, the heat generation layer 511 may be retained, such that the heat generation layer 511 may be cyclically used, and manufacturing costs may be saved.

According to the present disclosure, a display panel is provided. The display panel includes the glass substrate 1, the plurality of light emitting units 2, the plurality of first bonding portions 4, and the silicon-based driver substrate 6. The glass substrate includes the first surface 11 and the second surface 12 opposite to the first surface 11, and the glass substrate 1 defines the plurality of conductive through holes 13 extending from the first surface 11 to the second surface 12. The plurality of conductive through holes 13 include the plurality of first conductive through holes 131. The plurality of light emitting units 2 are disposed on the first surface of the glass substrate 1. Each of the plurality of light emitting units 2 includes the anode electrode 21, the organic light emitting layer 22, and the cathode electrode 23 that are stacked sequentially along a direction extending away from the glass substrate 1. Each of the plurality of first bonding portions 4 is arranged in a respective one of the plurality of first conductive through holes 131. Each first bonding portion 4 is electrically connected, through the respective first conductive through hole 13, to the anode electrode 21 of a respective one of the plurality of light emitting units 2. The silicon-based driver substrate 6 is arranged on a side of the second surface 12 of the glass substrate 1 and includes the protection layer 62 and the plurality of first bonding electrodes 61 arranged on a side near the glass substrate 1. The plurality of first bonding electrodes 61 are aligned to and bonded with the plurality of first bonding portions 4 in one-to-one correspondence manner. At least part of the first bonding electrodes 61 are embedded in the protection layer 62. A side of the second surface 12 of the glass substrate 1 and the side surface of the protection layer 62 facing the glass substrate 1 cooperatively form the receiving space 5. The excitation member 51 and the drive member 52 are arranged in the receiving space 5. The excitation member 51 is configured to provide excitation. In response to the excitation provided by the excitation member 51, the drive member 52 applies a pressure to the glass substrate 1 and the protection layer 62, respectively. By arranging the light emitting units 2 and the first bonding portions 4 respectively on two opposite surfaces of the glass substrate 1, each of the plurality of first bonding portions 4 is electrically connected, through the respective first conductive through hole 13, to the anode electrode 21 of the respective light emitting unit 2 to electrically connect the light emitting unit 2 with the silicon-based driver substrate 6, such that the silicon-based driver substrate 6 may drive the plurality of light emitting units 2 to emit light. In this way, the plurality of light emitting units 2 may not be directly prepared on the silicon-based driver substrate 6, and damages to the pixel driver circuit 64, caused by directly preparing the light emitting units 2 on the silicon-based driver substrate 6, may be avoided, and therefore, a product yield may not be affected. Further, by arranging the excitation member 51 and the drive member 52 in the receiving space 5 between the glass substrate 1 and the silicon-based driver substrate 6, when the glass substrate 1 and the silicon-based driver substrate 6 need to be peeled apart from each other due to a process problem occurring during preparing the display panel, the excitation member 51 may drive the drive member 52 to apply the pressure towards two opposite directions respectively to the glass substrate 1 and the silicon-based driver substrate 6. In this way, the glass substrate 1 and the silicon-based driver substrate 6 may be easily peeled apart from each other, such that a peeling efficiency may be improved.

The above is only an implementation of the present disclosure, and is not intended to limit the scope of the present disclosure. Any equivalent structure or equivalent process transformation performed based on the contents of the specification and the accompanying drawings of the present disclosure, applied directly or indirectly in other related technical fields, shall be equivalently included in the scope of the present disclosure.

What is claimed is:

1. A display panel, comprising:
a glass substrate, comprising a first surface and a second surface opposite to the first surface, wherein the glass substrate defines a plurality of conductive through holes extending from the first surface to the second surface; the plurality of the conductive through holes comprises a plurality of first conductive through holes;
a plurality of light emitting units, arranged on the first surface of the glass substrate; each of the plurality of light emitting units comprises an anode electrode, an organic light emitting layer, and a cathode electrode that are stacked sequentially in a direction away from the glass substrate;
a plurality of first bonding portions, wherein each of the plurality of first bonding portions is received in a respective one of the plurality of first conductive through holes; each of the plurality of first bonding portions is electrically connected, through the respective first conductive through hole, to the anode electrode of a respective one of the plurality of light emitting units;
a silicon-based driver substrate, arranged at a side of the second surface of the glass substrate and comprising a protection layer and a plurality of first bonding electrodes arranged on a side of the silicon-based driver substrate near the glass substrate; wherein the plurality of first bonding electrodes are aligned to and bonded with the plurality of first bonding portions in one-to-one correspondence manner; at least part of the plurality of first bonding electrodes are embedded in the protection layer;
wherein a side of the second surface side of the glass substrate and a side of the protection layer facing the glass substrate cooperatively form a plurality of receiving spaces; each of the plurality of receiving spaces receives an excitation member and a drive member; the excitation member is configured to provide excitation; in response to the excitation provided by the excitation member, the drive member is configured to apply a pressure to the glass substrate and the protection layer, respectively.

2. The display panel according to claim 1, wherein,
the excitation member comprises a heat generation layer; and the drive member comprises a reaction layer;
the heat generation layer is configured to generate heat and heat the reaction layer; in response to a temperature of the reaction layer being greater than a predetermined temperature, the reaction layer is configured to generate a gas and to apply the pressure to the glass substrate and the protection layer, respectively.

3. The display panel according to claim 2, wherein the heat generation layer comprises a wave-absorbing material configured to convert ultrasonic waves into thermal energy.

4. The display panel according to claim 2, wherein the heat generation layer comprises a wave-absorbing material configured to convert electromagnetic energy into thermal energy.

5. The display panel according to claim 4, wherein the wave-absorbing material comprises at least one of: carbon nanotubes, graphene, conductive polymers, metal nanoparticles, porous ceramic materials, and magnetic nanoparticles.

6. The display panel according to claim 3, wherein,
the heat generation layer is a carbon nanotube composite layer; the carbon nanotube composite layer is capable of generating heat under excitation of ultrasonic waves of a predetermined frequency; wherein the predetermined frequency is in a range of 8 GHz to 40 GHz; and
the reaction layer is a magnesium bicarbonate nanoparticle film; the magnesium bicarbonate nanoparticle film is configured to undergo a decomposition reaction and to generate water vapor and carbon dioxide in response to a temperature being greater than a predetermined temperature; wherein the predetermined temperature is greater than or equal to 180° C. and less than or equal to 220° C.

7. The display panel according to claim 2, wherein, the heat generation layer is electrically connected to a driver circuit of the silicon-based driver substrate to convert electrical energy into thermal energy; in response to the driver circuit transmitting an electrical signal to the heat generation layer, the heat generation layer is configured to generate heat and heat the reaction layer.

8. The display panel according to claim 2, wherein, the gas generated by the reaction layer is non-oxidative gas, and the non-oxidative gas comprises carbon dioxide.

9. The display panel according to claim 6, wherein a drying layer is further arranged in each of the plurality of receiving spaces and is configured to absorb the water vapor generated from the decomposition reaction occurring in the reaction layer; and
the drying layer, the reaction layer, and the heat generation layer are sequentially stacked.

10. The display panel according to claim 9, wherein the heat generation layer wraps a side surface of the reaction layer away from the drying layer and two side surfaces of the reaction layer located along a first direction perpendicular to a stacking direction of the display panel.

11. The display panel according to claim 9, wherein,
one of the second surface of the glass substrate and a side surface of the protection layer facing the glass substrate defines a plurality of first recesses; and the other one of the second surface of the glass substrate and the side surface of the protection layer facing the glass substrate defines a plurality of second recesses; each of the plurality of first recesses and a respective one of the plurality of second recesses are communicated to each other to form a respective one of the plurality of receiving spaces; a projection of each of the plurality of second recesses on the glass substrate along a stacking direction of the display panel is at least partially overlapping with a projection of the respective one of the plurality of first recesses on the glass substrate along the stacking direction;
the drying layer is received in the second recess; the drying layer is arranged on a side surface of the reaction layer away from the heat generation layer.

12. The display panel according to claim 11, wherein,
the plurality of first recesses are defined in the second surface of the glass substrate; the plurality of second recesses are defined in the side surface of the protection layer facing the glass substrate.

13. The display panel according to claim 11, wherein,
the plurality of first recesses are defined in the side surface of the protection layer facing the glass substrate; the plurality of second recesses are defined in the second surface of the glass substrate.

14. The display panel according to claim 11, wherein,
the plurality of first recesses are defined in the second surface of the glass substrate; the plurality of second recesses are defined in the side surface of the protection layer facing the glass substrate; a depth of each of the plurality of first recesses is less than or equal to one-third of a thickness of the glass substrate; a depth of each of the plurality of second recesses is less than or equal to one-half of a thickness of the protection layer.

15. The display panel according to claim 11, wherein,
the plurality of first recesses are spaced apart from the plurality of first conductive through holes; wherein a distance between each of the plurality of first recesses and a respective one of the plurality of first conductive through holes is greater than or equal to 2 μm and less than or equal to 3 μm; the plurality of second recesses are spaced apart from the plurality of first bonding electrodes; a distance between each of the plurality of second recesses and a respective one of the plurality of first bonding electrodes is greater than or equal to 2 μm and less than or equal to 3 μm.

16. The display panel according to claim 11, wherein,
a width of each of the plurality of first recesses is greater than or equal to 1 μm and less than or equal to 1.5 μm.

17. The display panel according to claim 11, wherein
two of the plurality of first recesses are respectively arranged at two sides of each of the plurality of first conductive through holes along a first direction perpendicular to the stacking direction.

18. The display panel according to 17, wherein the two first recesses are distributed symmetrically about the first conductive through hole.

19. The display panel according to claim 11, wherein,
each of the plurality of first recesses comprises a plurality of sub-recesses, the plurality of sub-recesses are spaced apart from each other and are arranged surrounding a circumference of each of the plurality of first conductive through holes.

20. The display panel according to claim 11, wherein,
a projection of each of the plurality of first recesses on the glass substrate along the stacking direction is annular; each of the plurality of first recesses and a respective one of the plurality of first conductive through holes are coaxially arranged with each other.
